(19) United States
(12) Patent Application Publication
(10) Pub. No.: US 2026/0111310 A1
(43) Pub. Date: Apr. 23, 2026

(54) FLASH MEMORY CONTROLLER AND CODING METHOD SUPPORTING MULTI-CODING MODE CODING OPERATIONS IN RESPONSE TO DIFFERENT PAGE SIZES

(71) Applicant: Silicon Motion, Inc., Hsinchu County (TW)

(72) Inventors: Duen-Yih Teng, Hsinchu County (TW); Shiuan-Hao Kuo, New Taipei City (TW)

(73) Assignee: Silicon Motion, Inc., Hsinchu County (TW)

(21) Appl. No.: 18/920,966

(22) Filed: Oct. 20, 2024

(51) Int. Cl. G06F 11/10

(52) U.S. Cl. CPC G06F 11/1068; G06F 11/1004

(57) ABSTRACT

A coding method of a flash memory controller includes: performing a local encoding operation upon a data unit to be written into a portion of a page unit of the flash memory device and to perform a global encoding operation upon multiple data units to be written into the page unit according to a coding matrix so as to generate and write error correction code data into the page unit; performing a local decoding operation upon the data unit read from the portion of the page unit and to perform a global decoding operation upon the multiple data units read from the page unit according to the error correction code data corresponding to the coding matrix to obtain correct data of the page unit; and, dynamically determining the coding matrix to dynamically select a coding mode.

### BACKGROUND OF THE INVENTION

### 1. Field of the Invention

The invention relates to a flash memory controller scheme, and a flash memory controller and a corresponding coding method.

### 2. Description of the Prior Art

Generally speaking, a conventional flash memory controller supports merely one kind of coding mode corresponding to a fixed data length (e.g. an LDPC (low density parity check) codeword having a fixed bit length), and thus the conventional flash memory controller cannot meet the requirements of different flash memory vendors which may manufacture different kinds of flash memory devices such as different kinds of flash memory chip dies having page units with different page sizes.

### SUMMARY OF THE INVENTION

Therefore one of the objectives of the invention is to provide a flash memory controller and a corresponding coding method, to solve the above mentioned problems.

According to an embodiment of the invention, a flash memory controller is disclosed. The flash memory controller is to be coupled between a host device and a flash memory device, and it comprises an encoder circuit, a decoder circuit, and a processing circuit. The encoder circuit is used for performing a local encoding operation upon a data unit to be written into a portion of a page unit of the flash memory device and performing a global encoding operation upon multiple data units to be written into the page unit according to a coding matrix so as to generate and write error correction code data into the page unit. The decoder circuit is used for performing a local decoding operation upon the data unit read from the portion of the page unit and performing a global decoding operation upon the multiple data units read from the page unit according to the error correction code data corresponding to the coding matrix to obtain correct data of the page unit. The processing circuit is coupled to the encoder circuit and the decoder circuit and is used for dynamically determining the coding matrix to dynamically select a coding mode.

According to an embodiment of the invention, a coding method of a flash memory controller to be coupled between a host device and a flash memory device is disclosed. The coding method comprises: providing an encoder circuit to perform a local encoding operation upon a data unit to be written into a portion of a page unit of the flash memory device and to perform a global encoding operation upon multiple data units to be written into the page unit according to a coding matrix so as to generate and write error correction code data into the page unit; providing a decoder circuit to perform a local decoding operation upon the data unit read from the portion of the page unit and to perform a global decoding operation upon the multiple data units read from the page unit according to the error correction code data corresponding to the coding matrix to obtain correct data of the page unit; and, dynamically determining the coding matrix to dynamically select a coding mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a flash memory controller according to an embodiment of the invention.

FIG. 2 is a diagram of the encoder circuit in FIG. 1 according to an embodiment of the invention.

FIG. 3 is a diagram of a coding matrix used by the encoder circuit according to an embodiment of the invention.

FIG. 4 is a diagram showing different examples of outputted data and parity data in different modes corresponding to the different data lengths of 4 KB, 8 KB, and 16 KB according to an embodiment of the invention.

FIG. 5 is a diagram of a different coding matrix used by the encoder circuit according to another embodiment of the invention.

FIG. 6 is a diagram of a different coding matrix used by the encoder circuit according to another different embodiment of the invention.

FIG. 7 is a diagram of a flowchart of decoding operations of the decoder circuit of FIG. 1 according to an embodiment of the invention.

FIG. 8 is a diagram of the decoder circuit according to an embodiment of the invention.

### DETAILED DESCRIPTION

The invention aims at providing a multi-mode coding scheme applied into a flash memory controller and a corresponding coding method of the flash memory controller. The flash memory controller, including the multi-mode encoder circuit and decoder circuit such as multi-mode LDPC (low density parity check) encoder and decoder for error correction code (ECC) operation, can be applied into different flash memory chip die devices and capable of making full use of the pages of the different flash memory chip die devices having different page sizes manufactured by different chip vendors. The multi-mode LDPC coding scheme is applied into the flash memory controller so that the flash memory controller can support different lengths of parity bits in different LDPC modes and achieve a friendly coding effect.

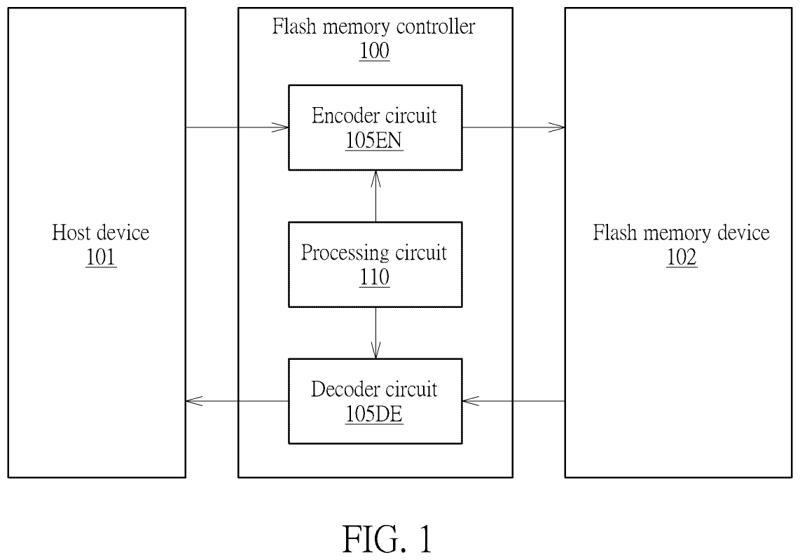

FIG. 1 is a diagram of a flash memory controller 100 according to an embodiment of the invention. The flash memory controller 100 is to be coupled between the host device 101 (e.g. a computer device) and a flash memory device 102 (e.g. an NAND-type flash memory chip die device), and it at least comprises an encoder circuit 105EN, a decoder circuit 105DE, and a processing circuit 110. The encoder circuit 105EN and decoder circuit 105DE support multi-mode encoding and decoding operations respectively, and the processing circuit 110 is used to send control signals to control mode selections of encoder circuit 105EN and decoder circuit 105DE.

The host device 101 may transmit a data, to be written or programmed into the flash memory device 102, from the host device 101 into a page unit of the flash memory controller 100, and the data may be formed by a sequence of data units which are sequentially received by the flash memory controller 100. For example (but not limited), the page unit at most can be used to store four data units each being 4 KB (the tailing ‘KB’ means kilobytes) and corresponding parity data which may be ranged from 1200 B (the tailing ‘B’ means bytes) to 4400 B (the tailing ‘B’ means bytes) in response to the design requirements of different chip die vendors. That is, the page unit can be used to store 16 KB data and parity data ranged from 1200 bytes to 4400 bytes. In this embodiment, a basic data unit, to be written into the flash memory device 102 or to be read from the flash memory device 102, has 4 KB data size. That is, the page unit can store four data units; this is not intended be a limitation of the invention. The size of a basic data unit may be variable in different modified embodiments. The flash memory controller 100, which supports the multi-mode LDPC coding scheme, can appropriately generate enough long parity data to support the page size ranged from 16 KB plus 1200 bytes to 16 KB plus 4400 bytes so as to improve the decoding capability with less power consumption and less hardware resource of encoding.

Based on the multi-mode coding scheme, when the host device 101 transmit a data unit (e.g. 4 KB), to be written/programmed into a page unit of the flash memory device 102, from the host device 101 into the flash memory controller 100, the flash memory controller 100 uses its encoder circuit 105EN to perform a local encoding operation such as LDPC encoding operation upon the received data unit to be written, to generate error correct code data (e.g. a local parity data) which is appended after the received data unit according to a coding matrix, and to write the data unit and the appended local parity data into a page unit of the flash memory device 102. In addition, the encoder circuit 105EN performs a global encoding operation the sequence of data units such as four data units which are to be written into the page unit according to the coding matrix so as to generate error correct code data (e.g. a global parity data) which is for example appended after the local parity data and to be written in to the page unit.

When the host device 101 requests a specific data such as a sequence of four data units stored in the page unit of the flash memory device 102, the flash memory controller 100 sequentially reads the four data units from the page unit of flash memory device 102, uses its decoder circuit 105DE to perform a corresponding local decoding operation (e.g. LDPC decoding operation) upon a specific data unit among the four data units (i.e. a portion data of the page unit) and to perform a corresponding global decoding operation upon the four data units read from the page unit according to the error correction data read from the page unit to obtain correct data of the page unit. For example, the decoder circuit 105DE performs the local decoding operation based on the local parity data read from the page unit and performs the global decoding operation based on the global parity data read from the page unit. The local decoding operation and global decoding operation can correct the requested data unit if an error occurs in the requested data unit, and transmits the correct data of the requested data unit back to the host device 101. The processing circuit 110, coupled to the encoder circuit 105EN and the decoder circuit 105DE, is used for dynamically determining the coding matrix to dynamically select a coding mode.

For example, the processing circuit 110 dynamically determines the coding matrix in response to the page size of the page unit. The actual size of a page unit in the flash memory device 102 may be variable since the flash memory device 102 may be manufactured by different flash memory vendors. In the embodiments, the processing circuit 110 can control the mode switching of encoder circuit 105EN to generate and output different parity data having different data lengths in response to the different sizes of different kinds of page units specified by different flash memory vendors, and can also correspondingly control the mode switching of decoder circuit 105DE to use the different parity data having different data lengths to decode the stored data in response to the different sizes of different kinds of page units specified by different flash memory vendors. In the different coding modes, the generated parity data are different, and the data lengths of the generated parity data are different.

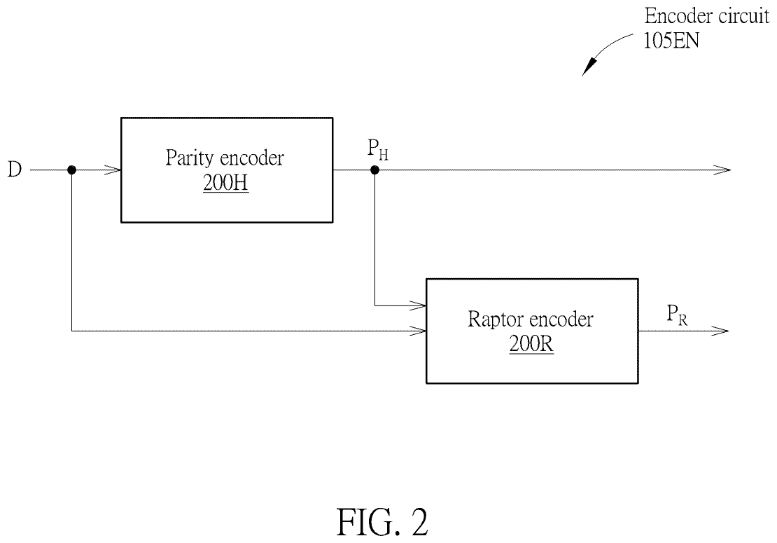

FIG. 2 is a diagram of the encoder circuit 105EN in FIG. 1 according to an embodiment of the invention. In FIG. 2, the encoder circuit 105EN comprises a parity encoder 200H and a raptor encoder 200R. The parity encoder 200H performs the local encoding operation upon the data unit to be written into the portion of the page unit of the flash memory device 102 according to a basic parity check matrix of the coding matrix to generate a parity data (i.e. a local parity data). For example, the parity encoder 200H uses a parity check matrix (i.e. the basic parity check matrix) to perform an error correction coding upon the data D, to be written, sent from the host device 101 to generate parity data P_{H}, i.e. a sequence of parity bits. In addition, the raptor encoder 200R, coupled to the parity encoder 200H, performs the global encoding operation upon the four data units, to be written into the page unit, and multiple parity data of the four data units according to a raptor matrix of the coding matrix to generate a raptor parity data (i.e. a global parity data). For example, the raptor encoder 200R uses the raptor matrix to perform another error correction coding upon the data D, to be written, sent from the host device 101 and upon the generated local parity data P_{H} so as to generate a raptor parity data P_{R}. The encoder circuit 105EN can dynamically determine whether to output raptor parity data P_{R} into the flash memory device 102 in response to the different selected modes. The operations of raptor encoder 200R are involved with a raptor matrix (e.g. a sparse matrix) and generation of raptor codes which are a type of fountain codes and are not detailed for brevity.

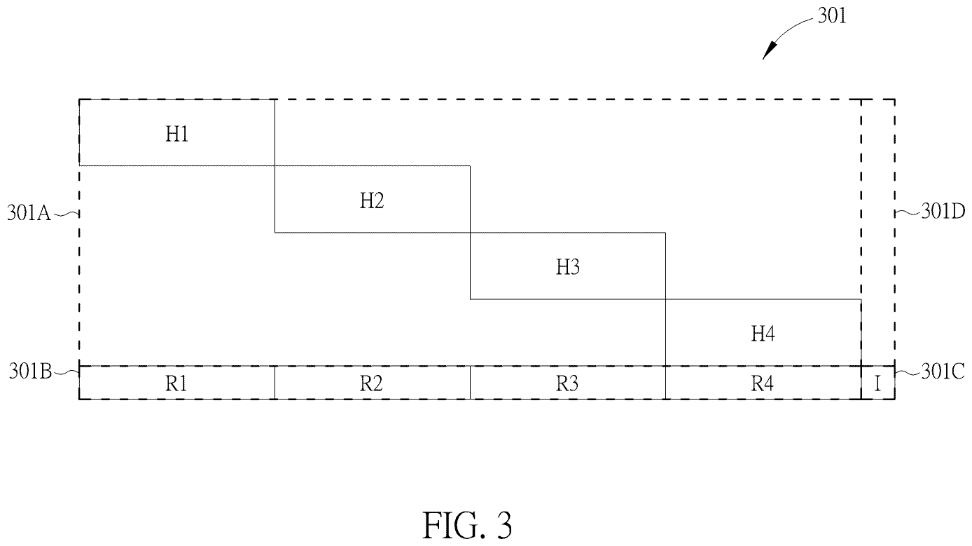

FIG. 3 is a diagram of a coding matrix 301 used by the encoder circuit 105EN according to an embodiment of the invention. As shown in FIG. 3, the coding matrix 301 is formed by four sub-matrix parts 301A-301D in which a first sub-matrix part 301A comprises multiple basic parity check matrix units H1-H4, a second sub-matrix part 301B comprises at least one raptor matrix unit such as four raptor matrix units R1-R4, a third sub-matrix part 301C comprises an identity matrix unit I, and a fourth sub-matrix part 301D comprises a zero matrix unit. The first sub-matrix part 301A for example is a matrix arranged by 4×m rows and 4×n columns and for example comprises four basic parity check matrix units H1-H4 each being arranged by m rows and n columns and being respectively disposed in a diagonal line from the top-left corner of first sub-matrix part 301A to the bottom-right corner of first sub-matrix part 301A while the values of other coefficients in the first sub-matrix part 301A are zero. The four basic parity check matrix units H1-H4 have identical/different coefficient values. For example, the parity check matrix units H1-H4 are an identical spare matrix being mostly zeros with a low density of ones; each row represents a parity check equation, and each column represents a bit in the codeword. The values of n and m are positive integers and are not intended to be a limitation of the invention. That is, the number of rows indicates the number of parity check equations, and the number of columns indicates the data length of the codeword. The second sub-matrix part 301B is a raptor matrix for example having one or more raptor matrix units. For example, a raptor matrix unit is a matrix arranged by one row and 4×n columns, which is formed by four basic raptor matrix units R1-R4 which are sequentially appended. The row number of the third sub-matrix part 301C is identical to that of second sub-matrix part 301B, and the row number and column number of third sub-matrix part 301C are identical. The row number of the fourth sub-matrix part 301D is identical to that of the first sub-matrix part 301A, and the column number of the fourth sub-matrix part 301D is identical to that of the third sub-matrix part 301C.

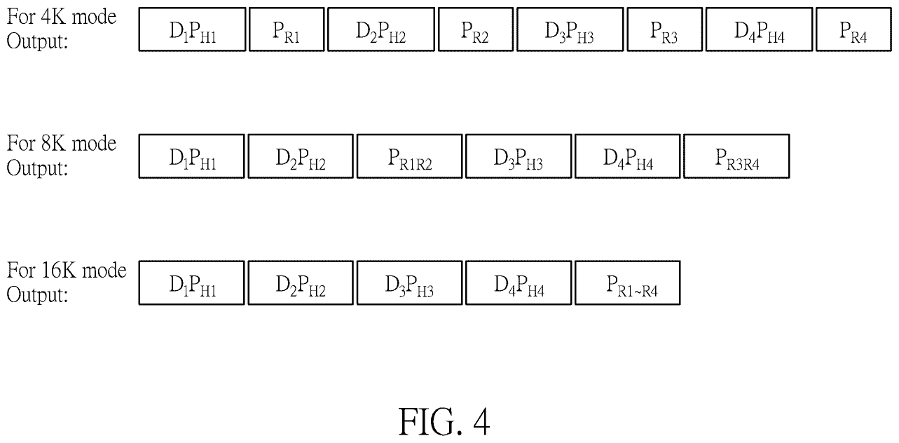

Based on the coding matrix 301, the encoder circuit 105EN for example may have three different coding modes in response to three different data lengths 4 KB, 8 KB, and 16 KB of different codewords. The processing circuit 110 can select and control the coding mode used by the encoder circuit 105EN. FIG. 4 is a diagram showing different examples of outputted data and parity data in different coding modes corresponding to the different data lengths 4 KB, 8 KB, and 16 KB according to an embodiment of the invention. For example, the host device 101 may sequentially send the data to be written into a page unit, e.g. a sequence of four 4 KB data D₁, D₂, D₃, and D₄, into the flash memory controller 100. As shown in FIG. 4, the processing circuit 110 selects a first coding mode corresponding to the data length 4 KB (i.e. the length of one basic data unit), and when receiving the first 4 KB data D₁ the parity encoder 200H uses the basic parity check matrix unit H1 to perform a local encoding operation upon the first 4 KB data D₁ to generate a first parity data P_{H1}, i.e. a sequence of first parity bits, and then the raptor encoder 200R uses the first basic raptor matrix unit R1 to perform another local encoding operation upon the first 4 KB data D₁ and generated first parity data P_{H1} so as to generate a first raptor parity data P_{R1}.

Similarly, when receiving the second 4 KB data D₂, the parity encoder 200H uses the basic parity check matrix unit H2 to perform a local encoding operation upon the second 4 KB data D₂ to generate a second parity data P_{H2}, and then the raptor encoder 200R uses the basic raptor matrix unit R2 to perform another local encoding operation upon the second 4 KB data D₂ and generated second parity data P_{H2} so as to generate a second raptor parity data P_{R2}. Similarly, when receiving the third 4 KB data D₃, the parity encoder 200H uses the basic parity check matrix unit H3 to perform a local encoding operation upon the third 4 KB data D₃ to generate a third parity data P_{H3}, and then the raptor encoder 200R uses the basic raptor matrix unit R3 to perform another local encoding operation upon the third 4 KB data D₃ and generated third parity data P_{H3} so as to generate a third raptor parity data P_{R3}. Similarly, when receiving the fourth 4 KB data D₄, the parity encoder 200H uses the basic parity check matrix unit H4 to perform a local encoding operation upon the fourth 4 KB data D₄ to generate a fourth parity data P_{H4}, and then the raptor encoder 200R uses the basic raptor matrix unit R4 to perform another local encoding operation upon the fourth 4 KB data D₄ and generated fourth parity data P_{H4} so as to generate a fourth raptor parity data P_{R4}.

By doing so, in the first coding mode corresponding to the data length 4 KB (i.e. a portion data of a page unit), the data to be outputted and written into a page unit of flash memory device 102 sequentially comprises D₁, P_{H1}, P_{R1}, D₂, P_{H2}, P_{R2}, D₃, P_{H3}, P_{R3}, D₄, P_{H4}, P_{R4}, as shown in FIG. 4; equivalently, in this example of first coding mode, the encoder circuit 105EN does not perform the global encoding operation upon the data and performs different local LDPC encoding operations upon the data.

In another example, the processing circuit 110 may select a second coding mode corresponding to the data length 8 KB (i.e. the length of two basic data units), and when receiving the first 4 KB data D₁ the parity encoder 200H uses the basic parity check matrix unit H1 to perform a local encoding operation upon the first 4 KB data D₁ to generate the first parity data P_{H1}, and the parity encoder 200H uses the basic parity check matrix unit H2 to perform a local encoding operation upon the second 4 KB data D₂ to generate the second parity data P_{H2} when receiving the second 4 KB data D₂. Then, the raptor encoder 200R uses the basic raptor matrix units R1 and R2 to perform another error correction encoding operation upon the first 4 KB data D₁ and second 4 KB data D₂ with the generated parity data P_{H1} and P_{H2} so as to generate the raptor parity data P_{R1R2}; it should be noted that in the example the another error correction encoding operation is regarded as a local encoding operation for the whole data of the page unit and can be also regarded as a global encoding operation for the two data units D₁ and D₂.

Similarly, when receiving the third 4 KB data D₃, the parity encoder 200H uses the basic parity check matrix unit H3 to perform a local encoding operation upon the 4 KB data D₃ to generate the parity data P_{H3}, and the parity encoder 200H uses the basic parity check matrix unit H4 to perform a local encoding operation upon the 4 KB data D₄ to generate the parity data P_{H4} when receiving the fourth 4 KB data D₄. Then, the raptor encoder 200R uses the basic raptor matrix units R3 and R4 to perform another error correction encoding operation upon the 4 KB data D₃ and 4 KB data D₄ with the generated parity data P_{H3} and P_{H4} so as to generate the raptor parity data P_{R3R4}. Also, it should be noted that in the example the another error correction encoding operation is regarded as a local encoding operation for the whole data of the page unit and can be also regarded as a global encoding operation for the two data units D₃ and D₄. By doing so, in the second coding mode corresponding to the data length 8 KB, the data to be outputted and written into a page unit of flash memory device 102 sequentially comprises D₁, P_{H1}, D₂, P_{H2}, P_{R1R2}, D₃, P_{H3}, D₄, P_{H4}, P_{R3R4}, as shown in FIG. 4.

In another example, the processing circuit 110 may select a third coding mode corresponding to the data length 16 KB (i.e. the data length of a page unit). When receiving the first 4 KB data D₁, the parity encoder 200H uses the basic parity check matrix unit H1 to perform a local encoding operation upon the first 4 KB data D₁ to generate the first parity data P_{H1}, and the parity encoder 200H uses the basic parity check matrix unit H2 to perform a local encoding operation upon the second 4 KB data D₂ to generate the second parity data P_{H2} when receiving the second 4 KB data D₂. When receiving the third 4 KB data D₃, the parity encoder 200H uses the basic parity check matrix unit H3 to perform a local encoding operation upon the third 4 KB data D₃ to generate the third parity data P_{H3}, and the parity encoder 200H uses the basic parity check matrix unit H4 to perform a local encoding operation upon the fourth 4 KB data D₄ to generate the fourth parity data P_{H4} when receiving the fourth 4 KB data D₄. Then, the raptor encoder 200R uses the basic raptor matrix units R1-R4 to perform another error correction coding (i.e. a global encoding operation) upon the four 4 KB data D₁-D₄ with the generated parity data P_{H1}-P_{H4} so as to generate the raptor parity data P_{R1˜R4} (i.e. a global raptor parity data). By doing so, in the third coding mode corresponding to the data length 16 KB, the data to be outputted and written into a page unit of flash memory device 102 sequentially comprises D₁, P_{H1}, D₂, P_{H2}, D₃, P_{H3}, D₄, P_{H4}, P_{R1˜R4}, as shown in FIG. 4. Further, the third coding mode can be regarded as a multi-coding mode which supports both the local encoding operation for each data unit and global encoding operation for all data units of one page unit. The flash memory controller 100 can dynamically select an appropriate coding mode to generate and output a codeword having an enough long parity data length which can be fitted with the different page sizes of page units of the flash memory devices 102 which may be manufactured by different flash memory vendors.

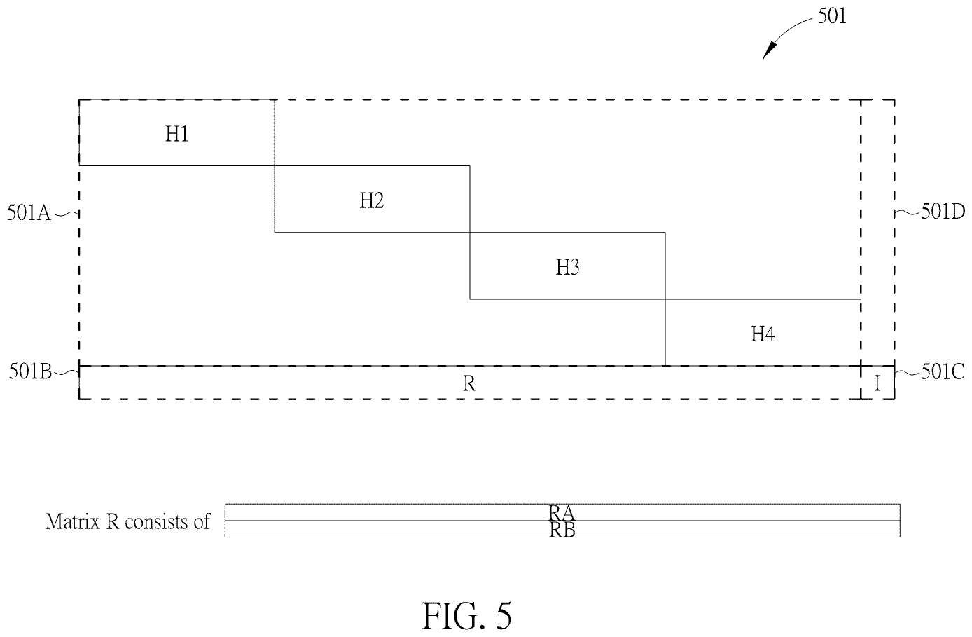

In addition, the raptor matrix may include more rows. FIG. 5 is a diagram of a different coding matrix 501 used by the encoder circuit 105EN according to another embodiment of the invention. As shown in FIG. 5, the coding matrix 501 is formed by four sub-matrix parts 501A-501D in which a first sub-matrix part 501A comprises multiple basic parity check matrix units H1-H4, a second sub-matrix part 501B comprises multiple one-row raptor matrix units, a third sub-matrix part 501C comprises an identity matrix unit I, and a fourth sub-matrix part 501D comprises a zero matrix unit having zeros. The first sub-matrix part 501A for example is a matrix arranged by 4×m rows and 4×n columns and for example comprises four basic parity check matrix units H1-H4 each being arranged by m rows and n columns and being respectively disposed in a diagonal line from the top-left corner of first sub-matrix part 501A to the bottom-right corner of first sub-matrix part 501A while the values of other coefficients in the first sub-matrix part 501A are zeros. The four basic parity check matrix units H1-H4 have identical/different coefficient values. For example, the parity check matrix units H1-H4 are an identical spare matrix being mostly zeros with a low density of ones; each row represents a parity check equation, and each column represents a bit in the codeword. The values of n and m are positive integers and are not intended to be a limitation of the invention. That is, the number of rows indicates the number of parity check equations, and the number of columns indicates the data length of the codeword. The second sub-matrix part 501B is for example a two-row raptor matrix R being formed by a first one-row raptor matrix unit RA arranged in one row with 4×n columns and a second one-row raptor matrix unit RB arranged in one row and 4×n columns; the one-row raptor matrix units can be different. For example, the first one-row raptor matrix RA may be formed by four basic raptor matrix units R1-R4 which are sequentially appended as shown in FIG. 3. In other embodiments, the second sub-matrix part 501B may be three-row raptor matrix, and the number of rows of the second sub-matrix part 501B is not intended to be a limitation of the invention.

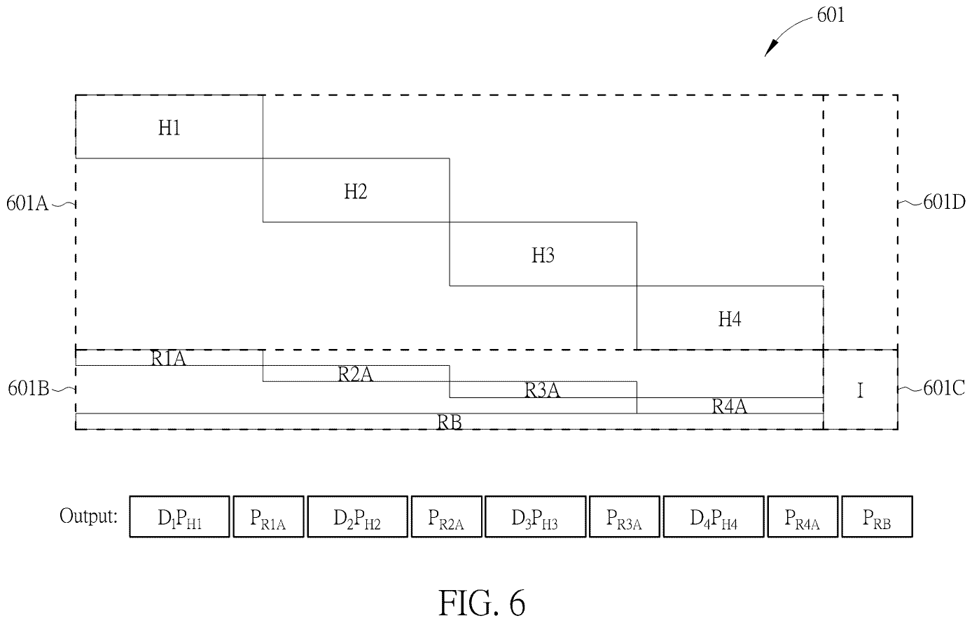

FIG. 6 is a diagram of a different coding matrix 601 used by the encoder circuit 105EN according to another different embodiment of the invention. As shown in FIG. 6, the coding matrix 601 is formed by four sub-matrix parts 601A-601D in which a first sub-matrix part 601A comprises multiple basic parity check matrix units H1-H4, a second sub-matrix part 601B comprises multiple-row raptor matrix units, a third sub-matrix part 601C comprises an identity matrix unit I, and a fourth sub-matrix part 601D comprises a zero matrix unit having zeros. The first sub-matrix part 601A for example is a matrix arranged by 4×m rows and 4×n columns and for example comprises four basic parity check matrix units H1-H4 each being arranged by m rows and n columns and being respectively disposed in a diagonal line from the top-left corner of first sub-matrix part 601A to the bottom-right corner of first sub-matrix part 601A while the values of other coefficients in the first sub-matrix part 601A are zeros. The four basic parity check matrix units H1-H4 have identical/different coefficient values. For example, the parity check matrix units H1-H4 are an identical spare matrix being mostly zeros with a low density of ones; each row represents a parity check equation, and each column represents a bit in the codeword. The values of n and m are positive integers and are not intended to be a limitation of the invention. That is, the number of rows indicates the number of parity check equations, and the number of columns indicates the data length of the codeword.

The second sub-matrix part 601B is for example a multi-row raptor matrix being formed by four basic one-row raptor matrix units R1A, R1B, R1C, and R1D, each being a matrix arranged in one row and n columns, and formed by an one-row raptor matrix unit RB which is a matrix arranged in one row and 4×n columns. The one-row raptor matrix unit RB is formed by another four basic one-row raptor matrix units which are sequentially appended in the horizontal direction. The four basic one-row raptor matrix units R1A, R1B, R1C, and R1D are disposed in a diagonal line from the top-left corner of the multi-row raptor matrix to the bottom-right corner of the multi-row raptor matrix while the values of other coefficients in the second sub-matrix part 601B are zeros. In addition, the identity matrix unit I comprised by the third sub-matrix part 601C is a matrix arranged in five rows and five columns. The zero matrix unit comprised by the fourth sub-matrix part 601D is a matrix arranged in 4×m rows and five columns.

Based on the coding matrix 601, the processing circuit 110 can select and control the coding mode used by the encoder circuit 105EN to perform a multi-mode encoding operation corresponding to both the data lengths 4 KB and 16 KB, i.e. the multi-coding mode supports both the local encoding operation for each data unit and the global encoding operation for all data units of one page unit. For example, the host device 101 may sequentially send the data to be written, e.g. a sequence of four 4 KB data D₁, D₂, D₃, and D₄, into the flash memory controller 100. The processing circuit 110 selects the multi-coding mode corresponding to both the data lengths 4 KB and 16 KB. When receiving the first 4 KB data D₁, the parity encoder 200H uses the basic parity check matrix unit H1 to perform a local encoding operation upon the first 4 KB data D₁ to generate the first parity data P_{H1}, i.e. a sequence of first parity bits, and then the raptor encoder 200R uses the first basic raptor matrix unit R1A to perform another local encoding operation upon the first 4 KB data D₁ and the generated first parity data P_{H1} so as to generate a first raptor parity data P_{R1A} (i.e. a local raptor parity data). Similarly, when receiving the second 4 KB data D₂, the parity encoder 200H uses the basic parity check matrix unit H2 to perform a local encoding operation upon the second 4 KB data D₂ to generate a second parity data P_{H2}, and then the raptor encoder 200R uses the basic raptor matrix unit R2A to perform another local encoding operation upon the second 4 KB data D₂ and generated second parity data P_{H2} so as to generate a second local raptor parity data P_{R2A}. Similarly, when receiving the third 4 KB data D₃, the parity encoder 200H uses the basic parity check matrix unit H3 to perform a local encoding operation upon the third 4 KB data D₃ to generate a third parity data P_{H3}, and then the raptor encoder 200R uses the basic raptor matrix unit R3A to perform another local encoding operation upon the third 4 KB data D₃ and generated third parity data P_{H3} so as to generate a third local raptor parity data P_{R3A}. Similarly, when receiving the fourth 4 KB data D₄, the parity encoder 200H uses the basic parity check matrix unit H4 to perform a local encoding operation upon the fourth 4 KB data D₄ to generate a fourth parity data P_{H4}, and then the raptor encoder 200R uses the basic raptor matrix unit R4A to perform another local encoding operation upon the fourth 4 KB data D₄ and generated fourth parity data P_{H4} so as to generate a fourth local raptor parity data P_{R4A}.

Then, the raptor encoder 200R uses the raptor matrix unit RB (arranged in one row and 4×n columns) to perform another error correction operation (i.e. a global encoding operation) upon the above data including the first 4 KB data D₁, first parity data P_{H1}, first local raptor parity data P_{R1A}, second 4 KB data D₂, second parity data P_{H2}, second local raptor parity data P_{R2A}, third 4 KB data D₃, third parity data P_{H3}, third local raptor parity data P_{R3A}, fourth 4 KB data D₄, fourth parity data P_{H4}, and fourth local raptor parity data P_{R4A} to generate the global raptor parity data P_{RB}. That is, the encoder circuit 105EN based on the coding matrix 601 of FIG. 6 can perform a parity encoding protection upon a sequence of 4 KB data, perform a local raptor encoding protection respectively upon the sequence of 4 KB data with corresponding parity data, and perform a global raptor encoding protection upon the sequence of 4 KB data with corresponding parity data and corresponding local raptor parity data, so as to generate a corresponding global raptor parity data. By doing so, in the multi-coding mode corresponding to the data lengths 4 KB and 16 KB, the data to be outputted and written into a page unit of flash memory device 102 sequentially comprises the first 4 KB data D₁, first parity data P_{H1}, first local raptor parity data P_{R1A}, second 4 KB data D₂, second parity data P_{H2}, second local raptor parity data P_{R2A}, third 4 KB data D₃, third parity data P_{H3}, third local raptor parity data P_{R3A}, fourth 4 KB data D₄, fourth parity data P_{H4}, fourth local raptor parity data P_{R4A}, and the global raptor parity data P_{RB}, as shown in FIG. 6.

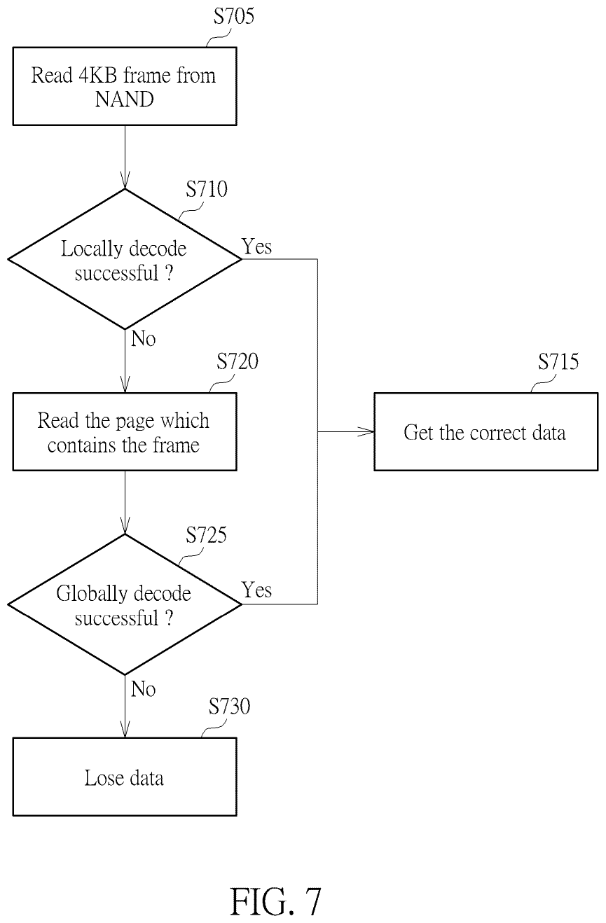

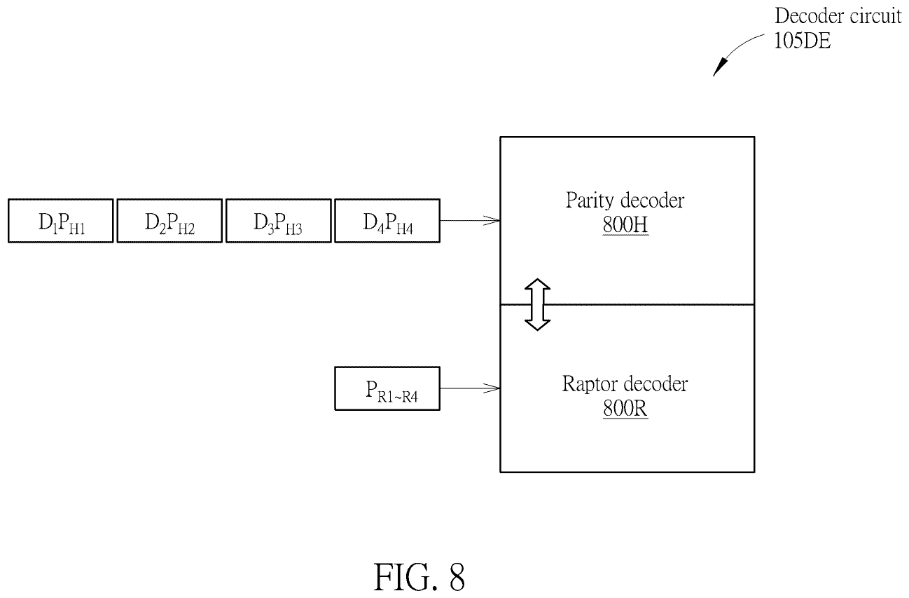

Refer to FIG. 7 in conjunction with FIG. 8. FIG. 7 is a diagram of a flowchart of decoding operations of the decoder circuit 105DE of FIG. 1 according to an embodiment of the invention. FIG. 8 is a diagram of the decoder circuit 105DE according to an embodiment of the invention. As shown in FIG. 7, in Step S705, the decoder circuit 105DE reads a portion of data stored in a page unit of the flash memory device 102, e.g. reading a portion of data such as one data unit (e.g. 4 KB frame data (or called as 4 KB chunk data)) from the flash memory device 102. In Step S710, the decoder circuit 105DE performs a local decoding operation upon the portion of data, e.g. the read 4 KB data. For example, the decoder circuit 105DE reads the first 4 KB data D₁ with the first parity data P_{H1} from the page unit of the flash memory device 102 to use the first parity data P_{H1} to perform the local decoding operation upon the first 4 KB data D₁ so as to correct error(s) in the read first 4 KB data D₁ if it is needed. If the number of errors is larger than the decoding capability of the first parity data P_{H1}, then the decoder circuit 105DE determines that the local decoding operation is not successful and thus the flow proceeds to Step S720. If the number of errors is equal to or smaller than the decoding capability of the first parity data P_{H1}, then the decoder circuit 105DE determines that the local decoding operation is successful and thus the flow proceeds to Step S715. In Step S715, the flash memory controller 100 gets the correct data such as the correct data of the first 4 KB data read from the flash memory device 102.

In Step S720, the decoder circuit 105DE is arranged to perform a global decoding operation. For example, the decoder circuit 105DE reads the other portions of data stored in the page unit of the flash memory device 102, e.g. reading the other three portions of data such as three 4 KB frame data (or called as 4 KB chunk data) from the flash memory device 102. That is, the decoder circuit 105DE reads the remaining data of the page unit which contains the frame data read in Step S705. In Step S725, the decoder circuit 105DE performs the global decoding operation upon the whole data of the page unit. For example, in Step S720, the decoder circuit 105DE reads the other 4 KB data D₂, D₃, D₄ with the other parity data P_{H2}, P_{H3}, P_{H4} and the raptor parity data such as P_{R1˜R4} from the page unit of the flash memory device 102 and then in Step S725 to use the other parity data P_{H2}, P_{H3}, P_{H4} to perform the other local decoding operations upon the 4 KB data D₂, D₃, D₄ and to perform the global decoding operation upon the 4 KB data D₁, D₂, D₃, D₄ and the parity data P_{H1}, P_{H2}, P_{H3}, P_{H4} so as to correct error(s) in the read 4 KB data D₁, D₂, D₃, D₄ and/or correct error(s) in the read parity data P_{H1}, P_{H2}, P_{H3}, P_{H4} if it is needed. If the number of errors is larger than the decoding capability of the raptor parity data P_{R1˜R4}, then the decoder circuit 105DE determines that the global decoding operation is not successful and thus the flow proceeds to Step S730 in which the decoder circuit 105DE determines that the data of the page unit is lost. If the number of errors is equal to or smaller than the decoding capability of the raptor parity data P_{R1˜R4}, then the decoder circuit 105DE determines that the global decoding operation is successful and thus the flow proceeds to Step S715 in which the decoder circuit 105DE determines that the correct data is obtained.

As shown in FIG. 8, the decoder circuit 105DE comprises a parity decoder 800H and a raptor decoder 800R coupled to the parity decoder 800H. For example, the parity decoder 800H is arranged to sequentially receive the 4 KB data D₁, D₂, D₃, D₄ and the parity data P_{H1}, P_{H2}, P_{H3}, P_{H4} as shown in FIG. 8 to perform the above-mentioned local decoding operation; that is, the parity decoder 800H may use the corresponding parity data P_{H1} to perform a decoding operation upon the 4 KB data D₁ to correct error(s) in the 4 KB data D₁ if it is needed. The raptor decoder 800R is coupled to the parity decoder 800H and is arranged to receive the global raptor parity data P_{R1˜R4} to use the global raptor parity data P_{R1˜R4} to perform the global decoding operation upon the 4 KB data D₁, D₂, D₃, D₄ and corresponding parity data P_{H1}, P_{H2}, P_{H3}, P_{H4}. For example, if the parity decoder 800H cannot successfully correct errors in the 4 KB data D₁ by using the parity data P_{H1}, then the result that the 4 KB data D₁ cannot successfully decoded is transmitted from the parity decoder 800H into the raptor decoder 800R, and the raptor decoder 800R may use the global raptor parity data P_{R1˜R4} to decode all the 4 KB data D₁, D₂, D₃, D₄ and corresponding parity data P_{H1}, P_{H2}, P_{H3}, P_{H4}. In this situation, if the raptor decoder 800R cannot successfully decode all the 4 KB data D₁, D₂, D₃, D₄ and corresponding parity data P_{H1}, P_{H2}, P_{H3}, P_{H4}, then the corresponding result is transmitted from the raptor decoder 800R into the parity decoder 800H, and the parity decoder 800 can be use to perform another local decoding operation upon the next 4 KB data D₂ by using the corresponding parity data P_{H2} to try to successfully correct errors in the 4 KB data D₂ by using the parity data P_{H2} if it is needed. Accordingly, in this embodiment, the local decoding result of parity decoder 800H can be referenced by the raptor decoder 800R to improve the accuracy of the global decoding operation, and the global decoding result of raptor decoder 800R can be also referenced by the parity decoder 800H to try to decode the other different data to improve accuracy of the global decoding operation performed for the next time.

In addition, it should be noted that the circuit structures of raptor decoder 800R may be similar to those of parity decoder 800H based on a min-sum algorithm of LDPC codes, and the raptor decoder 800R may use a register circuit to buffer the calculations of check node units (CNU) in the previous run(s), and this is not detailed for brevity.

Further, in other embodiments, taking an example of the data outputted and written into one page unit as shown in FIG. 6, the decoder circuit 105DE can perform two different local decoding operations upon each data unit (i.e. each 4 KB data frame/chunk) of one page unit. For example (but not limited), the decoder circuit 105DE may use the parity data P_{H1} to perform a first local decoding operation upon the data unit such as first 4 KB data D₁ read from a page unit, and may use the local raptor parity data P_{R1A} to perform a second local decoding operation upon the data unit such as first 4 KB data D₁ and parity data P_{H1} read from the page unit if the parity data P_{H1} cannot successfully decode the first 4 KB data D₁ read from the page unit. The operations and functions are similar to the steps mentioned in FIG. 7 and not detailed for brevity.

Further, the multi-mode coding scheme of the flash memory controller 100 can be suitable for different applications. For example, the flash memory controller 100 can use a coding mode corresponding to a shorter codeword length with a shorter parity length, e.g. the above-mentioned third coding mode corresponding to the length 16 KB, to protect data to be written into one page unit if the data error rate of the flash memory device 102 is lower, and it may use another coding mode corresponding to a longer codeword length with a longer parity length, e.g. the above-mentioned multi-coding mode as shown in FIG. 6, to protect data to be written into one page unit if the data error rate of the flash memory device 102 is higher. By doing this, the flash memory controller 100 can appropriately decrease the data error rate by a longer parity length. Similarly, in another example, the flash memory controller 100 can use a coding mode corresponding to a shorter codeword length with a shorter parity length, e.g. the above-mentioned third coding mode corresponding to the length 16 KB, to protect data to be written into one page unit if the program/erase (P/E) cycle of the flash memory device 102 is shorter, and it may use another coding mode corresponding to a longer codeword length with a longer parity length, e.g. the above-mentioned multi-coding mode as shown in FIG. 6, to protect data to be written into one page unit if the P/E cycle is longer. Similarly, in another example, the flash memory controller 100 can use a coding mode corresponding to a shorter codeword length with a shorter parity length, e.g. the above-mentioned third coding mode corresponding to the length 16 KB, to protect data to be written into one page unit if the page unit is involved with a programming mode of fewer bits per cell such as an SLC (single-level cell) mode, and it may use another coding mode corresponding to a longer codeword length with a longer parity length, e.g. the above-mentioned multi-coding mode as shown in FIG. 6, to protect data to be written into one page unit if the page unit is involved with a programming mode of more bits per cell such as an QLC (quad-level cell) mode. These medications all fall within the scope of the invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flash memory controller, to be coupled between a host device and a flash memory device, comprising:
an encoder circuit, for performing a local encoding operation upon a data unit to be written into a portion of a page unit of the flash memory device and performing a global encoding operation upon multiple data units to be written into the page unit according to a coding matrix so as to generate and write error correction code data into the page unit;
a decoder circuit, for performing a local decoding operation upon the data unit read from the portion of the page unit and performing a global decoding operation upon the multiple data units read from the page unit according to the error correction code data corresponding to the coding matrix to obtain correct data of the page unit; and
a processing circuit, coupled to the encoder circuit and the decoder circuit, for dynamically determining the coding matrix to dynamically select a coding mode.

2. The flash memory controller of claim 1, wherein the processing circuit dynamically determines the coding matrix in response to a page size of the page unit.

3. The flash memory controller of claim 1, wherein the encoder circuit comprises:
a parity encoder, for performing the local encoding operation upon the data unit to be written into the portion of the page unit of the flash memory device according to a basic parity check matrix of the coding matrix to generate a parity data; and
a raptor encoder, coupled to the parity encoder, for performing the global encoding operation upon the multiple data units, to be written into the page unit, and multiple parity data of the multiple data units according to a raptor matrix of the coding matrix to generate a raptor parity data.

4. The flash memory controller of claim 1, wherein when the processing circuit selects a first coding mode corresponding to a data length of a data unit, the encoder circuit performs an encoding operation upon the data unit to generate a corresponding parity data and performs another encoding operation upon the data unit and the corresponding parity data to generate a raptor parity data; when the processing circuit selects a second coding mode corresponding to a data length of two data units, the encoder circuit performs the encoding operation respectively upon the two data units to generate two corresponding parity data and performs the another encoding operation upon the two data unit and the two corresponding parity data to generate the raptor parity data; and, when the processing circuit selects a third coding mode corresponding to a data length of four data units, the encoder circuit performs the encoding operation respectively upon the four data units to generate four corresponding parity data and performs the another encoding operation upon the four data unit and the four corresponding parity data to generate the raptor parity data.

5. The flash memory controller of claim 1, wherein when the processing circuit selects a multi-coding mode corresponding to a data length of a data unit and a data length of four data units, the encoder circuit performs a first encoding operation upon the data unit to generate a corresponding parity data and performs a second encoding operation upon the data unit and the corresponding parity data to generate a local raptor parity data; and, the encoder circuit performs a third encoding operation upon the four data units, four corresponding parity data, and four local raptor parity data to generate a global raptor parity data.

6. The flash memory controller of claim 1, wherein the coding matrix comprises:
a first sub-matrix part, arranged in 4×m rows and 4×n columns, comprising four basic parity check matrix units arranged in a diagonal line from a top-left corner of the first sub-matrix part to a bottom-right corner of the first sub-matrix part, a basic parity check matrix unit being arranged in m rows and n columns;
a second sub-matrix part comprising at least one raptor matrix which is formed by four basic raptor matrix units each being arranged in one row and n columns;
a third sub-matrix part comprising an identify matrix; and
a fourth sub-matrix part being a zero matrix;
wherein the first sub-matrix part is disposed at a top-left position of the coding matrix, the second sub-matrix part is disposed at a bottom-left position of the coding matrix, the third sub-matrix part is disposed at a bottom-right position of the coding matrix, and the fourth sub-matrix part is disposed at a top-right position of the coding matrix.

7. The flash memory controller of claim 1, wherein the coding matrix comprises:
a first sub-matrix part, arranged in 4×m rows and 4×n columns, comprising four basic parity check matrix units arranged in a diagonal line from a top-left corner of the first sub-matrix part to a bottom-right corner of the first sub-matrix part, a basic parity check matrix unit being arranged in m rows and n columns;
a second sub-matrix part comprising two raptor matrix units in which a first raptor matrix unit is a matrix arranged in one-row and 4×n columns and disposed at a top position of the second sub-matrix part while a second raptor matrix unit is a different matrix arranged in one-row and 4×n columns and disposed at a bottom position of the second sub-matrix part;
a third sub-matrix part comprising an identify matrix arranged in two rows and two columns; and
a fourth sub-matrix part being a zero matrix arranged in 4×m rows and two columns;
wherein the first sub-matrix part is disposed at a top-left position of the coding matrix, the second sub-matrix part is disposed at a bottom-left position of the coding matrix, the third sub-matrix part is disposed at a bottom-right position of the coding matrix, and the fourth sub-matrix part is disposed at a top-right position of the coding matrix.

8. The flash memory controller of claim 1, wherein the coding matrix comprises:
a first sub-matrix part, arranged in 4×m rows and 4×n columns, comprising four basic parity check matrix units arranged in a diagonal line from a top-left corner of the first sub-matrix part to a bottom-right corner of the first sub-matrix part, a basic parity check matrix unit being arranged in m rows and n columns;
a second sub-matrix part comprising two raptor matrix units in which a first raptor matrix unit is a matrix arranged in four rows and 4×n columns and disposed at a top position of the second sub-matrix part while a second raptor matrix unit is a different matrix arranged in one-row and 4×n columns and disposed at a bottom position of the second sub-matrix part, the first raptor matrix unit comprising four basic raptor matrix units arranged in a diagonal line from a top-left corner of the first raptor matrix unit to a bottom-right corner of the first raptor matrix unit;
a third sub-matrix part comprising an identify matrix arranged in five rows and five columns; and
a fourth sub-matrix part being a zero matrix arranged in 4×m rows and five columns;
wherein the first sub-matrix part is disposed at a top-left position of the coding matrix, the second sub-matrix part is disposed at a bottom-left position of the coding matrix, the third sub-matrix part is disposed at a bottom-right position of the coding matrix, and the fourth sub-matrix part is disposed at a top-right position of the coding matrix.

9. The flash memory controller of claim 1, wherein the decoder circuit comprises:
a parity decoder, for performing the local decoding operation upon the data unit read from the portion of the page unit of the flash memory device according to the parity data read from the page unit; and
a raptor decoder, coupled to the parity decoder, for performing the global encoding operation upon the multiple data units and the multiple parity data read from the page unit according to the raptor parity data read from the page unit.

10. The flash memory controller of claim 1, wherein the decoder circuit is arranged to perform the global decoding operation after a result of the local decoding operation is not successful.

11. A coding method of a flash memory controller to be coupled between a host device and a flash memory device, and the coding method comprises:
providing an encoder circuit to perform a local encoding operation upon a data unit to be written into a portion of a page unit of the flash memory device and to perform a global encoding operation upon multiple data units to be written into the page unit according to a coding matrix so as to generate and write error correction code data into the page unit;
providing a decoder circuit to perform a local decoding operation upon the data unit read from the portion of the page unit and to perform a global decoding operation upon the multiple data units read from the page unit according to the error correction code data corresponding to the coding matrix to obtain correct data of the page unit; and
dynamically determining the coding matrix to dynamically select a coding mode.

12. The coding method of claim 11, wherein the coding matrix is dynamically determined in response to a page size of the page unit.

13. The coding method of claim 11, further comprising:
using a parity encoder to perform the local encoding operation upon the data unit to be written into the portion of the page unit of the flash memory device according to a basic parity check matrix of the coding matrix to generate a parity data; and
using a raptor encoder to perform the global encoding operation upon the multiple data units, to be written into the page unit, and multiple parity data of the multiple data units according to a raptor matrix of the coding matrix to generate a raptor parity data.

14. The coding method of claim 11, wherein:
when selecting a first coding mode corresponding to a data length of a data unit, performing an encoding operation upon the data unit to generate a corresponding parity data and performs another encoding operation upon the data unit and the corresponding parity data to generate a raptor parity data;
when selecting a second coding mode corresponding to a data length of two data units, performing the encoding operation respectively upon the two data units to generate two corresponding parity data and performs the another encoding operation upon the two data unit and the two corresponding parity data to generate the raptor parity data; and
when selecting a third coding mode corresponding to a data length of four data units, performing the encoding operation respectively upon the four data units to generate four corresponding parity data and performs the another encoding operation upon the four data unit and the four corresponding parity data to generate the raptor parity data.

15. The coding method of claim 11, wherein:
when selecting a multi-coding mode corresponding to a data length of a data unit and a data length of four data units, performing a first encoding operation upon the data unit to generate a corresponding parity data and performs a second encoding operation upon the data unit and the corresponding parity data to generate a local raptor parity data, and performing a third encoding operation upon the four data units, four corresponding parity data, and four local raptor parity data to generate a global raptor parity data.

16. The coding method of claim 11, wherein the coding matrix comprises:
a first sub-matrix part, arranged in 4×m rows and 4×n columns, comprising four basic parity check matrix units arranged in a diagonal line from a top-left corner of the first sub-matrix part to a bottom-right corner of the first sub-matrix part, a basic parity check matrix unit being arranged in m rows and n columns;
a second sub-matrix part comprising at least one raptor matrix which is formed by four basic raptor matrix units each being arranged in one row and n columns;
a third sub-matrix part comprising an identify matrix; and
a fourth sub-matrix part being a zero matrix;
wherein the first sub-matrix part is disposed at a top-left position of the coding matrix, the second sub-matrix part is disposed at a bottom-left position of the coding matrix, the third sub-matrix part is disposed at a bottom-right position of the coding matrix, and the fourth sub-matrix part is disposed at a top-right position of the coding matrix.

17. The coding method of claim 11, wherein the coding matrix comprises:
a first sub-matrix part, arranged in 4×m rows and 4×n columns, comprising four basic parity check matrix units arranged in a diagonal line from a top-left corner of the first sub-matrix part to a bottom-right corner of the first sub-matrix part, a basic parity check matrix unit being arranged in m rows and n columns;
a second sub-matrix part comprising two raptor matrix units in which a first raptor matrix unit is a matrix arranged in one-row and 4×n columns and disposed at a top position of the second sub-matrix part while a second raptor matrix unit is a different matrix arranged in one-row and 4×n columns and disposed at a bottom position of the second sub-matrix part;
a third sub-matrix part comprising an identify matrix arranged in two rows and two columns; and
a fourth sub-matrix part being a zero matrix arranged in 4×m rows and two columns;
wherein the first sub-matrix part is disposed at a top-left position of the coding matrix, the second sub-matrix part is disposed at a bottom-left position of the coding matrix, the third sub-matrix part is disposed at a bottom-right position of the coding matrix, and the fourth sub-matrix part is disposed at a top-right position of the coding matrix.

18. The coding method of claim 11, wherein the coding matrix comprises:
a first sub-matrix part, arranged in 4×m rows and 4×n columns, comprising four basic parity check matrix units arranged in a diagonal line from a top-left corner of the first sub-matrix part to a bottom-right corner of the first sub-matrix part, a basic parity check matrix unit being arranged in m rows and n columns;
a second sub-matrix part comprising two raptor matrix units in which a first raptor matrix unit is a matrix arranged in four rows and 4×n columns and disposed at a top position of the second sub-matrix part while a second raptor matrix unit is a different matrix arranged in one-row and 4×n columns and disposed at a bottom position of the second sub-matrix part, the first raptor matrix unit comprising four basic raptor matrix units arranged in a diagonal line from a top-left corner of the first raptor matrix unit to a bottom-right corner of the first raptor matrix unit;
a third sub-matrix part comprising an identify matrix arranged in five rows and five columns; and
a fourth sub-matrix part being a zero matrix arranged in 4×m rows and five columns;
wherein the first sub-matrix part is disposed at a top-left position of the coding matrix, the second sub-matrix part is disposed at a bottom-left position of the coding matrix, the third sub-matrix part is disposed at a bottom-right position of the coding matrix, and the fourth sub-matrix part is disposed at a top-right position of the coding matrix.

19. The coding method of claim 11, further comprising:
using a parity decoder to perform the local decoding operation upon the data unit read from the portion of the page unit of the flash memory device according to the parity data read from the page unit; and
using a raptor decoder to perform the global encoding operation upon the multiple data units and the multiple parity data read from the page unit according to the raptor parity data read from the page unit.

20. The coding method of claim 11, wherein the global decoding operation is performed after a result of the local decoding operation is not successful.
